(19) United States
(12) Patent Application Publication
(10) Pub. No.: US 2015/0159812 A1
(43) Pub. Date: Jun. 11, 2015

(54) SUBSTRATES WITH STIFFENERS FOR LIGHTING AND ELECTRONIC APPLICATIONS

(71) Applicants: Richard Speer, Concord, MA (US); David Hamby, Andover, MA (US); Kenneth Grossman, Beverly, MA (US)

(72) Inventors: Richard Speer, Concord, MA (US); David Hamby, Andover, MA (US); Kenneth Grossman, Beverly, MA (US)

(73) Assignee: OSRAM SYLVANIA INC., Danvers, MA (US)

(21) Appl. No.: 14/099,483

(22) Filed: Dec. 6, 2013

(51) Int. Cl. F21K 99/00; H05K 1/18

(52) U.S. Cl. CPC F21K 9/00; H05K 1/189; H05K 2201/10106; H05K 2201/2009

(57) ABSTRACT

Substrates for electronic components are disclosed. In some example embodiments, a light source is provided with a substrate, at least one electronic package coupled to said substrate by an adhesive at an associated mounting location, and a stiffener proximate to said mounting location for reducing flexing of said substrate in said mounting location compared to flexing of said substrate in said mounting location in the absence of said stiffener.

### TECHNICAL FIELD

The present disclosure relates to substrates for lighting and electronics applications, components thereof, and methods for manufacturing the same.

### BACKGROUND

Light sources such as incandescent and fluorescent sources are increasingly being replaced by light emitting diode (hereafter, LED or LEDs) sources. An LED light source may include a plurality of electronic packages, wherein each package includes one or more LED chips. The electronic package may include a plastic body that surrounds a lead frame that is configured to allow electrical connections to the LED chip(s). The body may be configured such that a volume remains above the LED chip. In some instances that volume may be filled with a wavelength conversion material (e.g., a phosphor) or another material that may affect the wavelength or other characteristics of the light emitted from the LED chip.

Electronic packages may be mounted on a circuit substrate that is made of relatively stiff material such as fiber reinforced epoxy (e.g., FR4). The circuit substrate may be processed to bear conductive traces or other components of a printed circuit on a surface thereof. The electronic packages may be mounted or otherwise coupled to the traces to produce a lighting array. Although such lighting arrays are useful, the use of relatively stiff circuit substrates may impose design limitations. Technology has therefore been developed to permit the use of circuit substrates that are manufactured from flexible materials such as plastics.

In some configurations a conductive epoxy or other adhesive may be used to adhere the electronic package to the substrate and maintain electrical contact between the electronic package and traces on the substrate. While this approach is useful in low stress applications, flexing of the substrate may cause the adhesive to crack, potentially compromising the electrical connection between the electronic package and corresponding electrical traces. Accordingly, there remains in need in the art for improved technologies for securing electronic packages to flexible substrates.

### BRIEF DESCRIPTION OF THE DRAWINGS

Reference is now made to the following detailed description which should be read in conjunction with the following figures:

FIG. 1 is a top view of one embodiment of a light source consistent with the present disclosure;

FIG. 2 is a top view of another embodiment of a light source consistent with the present disclosure;

FIG. 3A is a side view of a light source consistent with the present disclosure in a static or un-flexed state; and

FIG. 3B is a side view of the light source of FIG. 3A in a flexed state.

FIG. 4 is a cross sectional view of an embodiment having a configuration similar to FIG. 1.

### DETAILED DESCRIPTION

As used herein the terms “about” and “substantially” when used in connection with a numerical value or range, mean +/−5% of the recited numerical value or range.

One or more aspects of the present disclosure may be described using numerical ranges. Unless otherwise indicated herein, any recited range should be interpreted as including any and all iterative values between indicated endpoints, as if such iterative values were expressly recited. Such ranges should also be interpreted as including any and all ranges falling within or between such iterative values and/or recited endpoints, as if such ranges were expressly recited.

For purpose of the present disclosure it is to be understood that when one element or layer (first element) is referred to as being “on,” “connected to” or “coupled to” another element or layer (second element), the first element may be directly on, connected to or coupled to the second element, or one or more intervening elements or layers may be present between the first and second elements. In contrast, when an first element is referred to as being “directly on,” “directly connected to” or “directly coupled to” a second element, no intervening elements or layers present are present between the first and second elements.

As used herein the term “and/or” includes any and all combinations of one or more of an associated list of items.

For the sake of clarity the terms “first,” “second,” “third” etc. may be used to describe various elements, components, regions, layers and/or sections. It should be understood that this is for the sake of explanation only, and that such elements components, regions, layers and/or sections are not to be limited by such terms. Thus for example a first element, component, region, layer or section could be termed a second element, component, region, layer or section without departing from the scope and teachings of the present invention.

Spatially relative terms, such as “beneath,” “below,” “upper,” “lower,” “above” and the like may be used herein for ease of description to describe one element or feature's relationship to another element(s) or feature(s) as illustrated in the drawings. These spatially relative terms are intended to encompass different orientations of the device in use or operation in addition to the orientation shown in the drawings. For example, if the device in the drawings is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. For example, the singular terms “a,” “an” and “the” are intended to include their plural forms as well, unless the context clearly indicates otherwise.

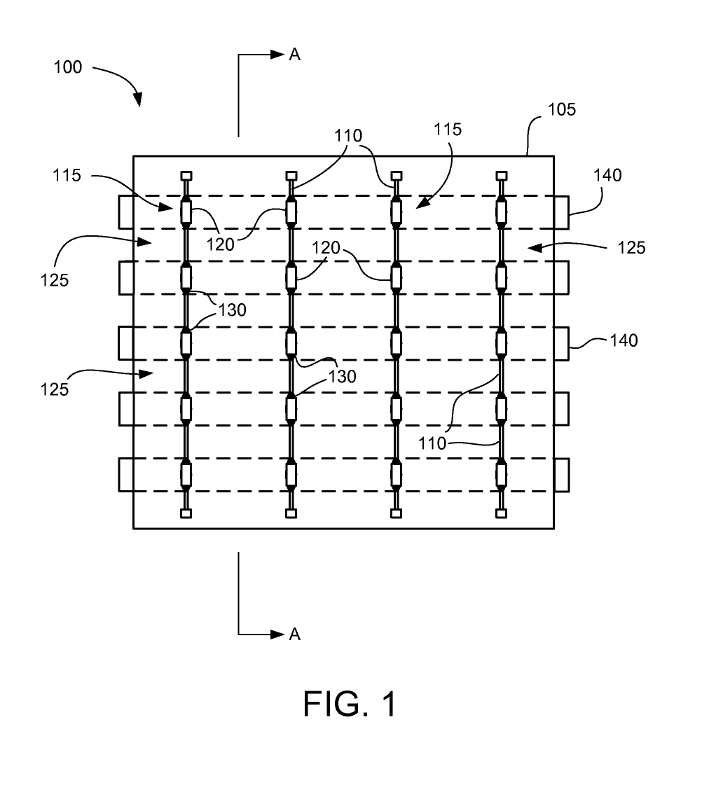

Reference is now made to FIG. 1, which is a top view of a light source 100 consistent with the present disclosure including a substrate 105 and a plurality of electronic packages 120. Each electronic package 120 may include one or more LEDs and/or other electronic components. Each electronic package 120 is coupled to the substrate 105 at a mounting location 115 an adhesive 130. The electronic packages 120 may be coupled to the substrate 105 such that electrical contacts of the electronic packages 120 are electrically coupled to associated conductive traces 110 on the substrate. Electrical power supplied to the conductive traces 110 may cause light to emanate from one or more LEDs within the package.

The substrate 105 may be formed from any material or combination of materials suitable for use as a substrate for a light source or other electronic device. In some embodiments, the substrate 105 is a flexible substrate and may therefore be in the form of a flexible sheet, a woven and/or non-woven material, a flexible composite, combinations thereof, and the like. The substrate 105 may, for example, be formed from any suitably flexible material, such as a polymer, a polymer composite, a polymer fiber composite, a metal, a laminate, or a combination thereof. Non-limiting examples of suitable polymer materials that may be used to form such sheets include shapeable polymers such as polyetheylene (PE), polypropylene (PP), polyethylene terephthalate (PET), polyimide (PI), polyamides, polyethylene napthalate (PEN), polyether ether ketone (PEEK), combinations thereof, and the like. As used herein, the term “flexible substrate” means that the substrate is capable of mechanically bending to such a degree that it can be rolled onto a 2-inch diameter cylinder without cracking or breaking.

In some embodiments, the substrate 105 may be a laminate substrate. For example, the substrate 105 may include one or more circuit components (e.g., traces) sandwiched between electrically insulating layers (not shown). Insulating layers may be formed of any electrically insulating material, such as but not limited to non-conductive polymers and composites. The insulating layers may be formed from the same non-conductive polymer material. Non-limiting examples of non-conductive polymer materials that may be used to form insulating layers include polyolefins such as polyethylene and polypropylene, polyesters such as PET, polyimides, and combinations thereof.

The traces 110 may be formed of any material with conductivity that is sufficient for electrical applications, e.g., for use as conductive traces of a circuit. Thus for example, traces 110 may be formed of a metal such as copper, silver, gold, aluminum, or the like, which may be printed, deposited, and/or plated on a surface of the substrate 105 so as to correspond to a desired pattern of a circuit. Alternatively or additionally, traces 110 may be formed by printing or depositing a conductive ink on a surface of the substrate 105. In some example embodiments, the conductive ink may include a binder material that is loaded with particles of conductive material such as silver, gold, copper, aluminum, and the like.

The adhesive 130 may be any suitable adhesive for electrically coupling and/or physically bonding traces to corresponding contacts of the electronic package 120. The adhesive may, for example, be an electrically conductive adhesive including, for example, conductive particles such as particles of silver, gold, copper, aluminum or the like. The particles may be present in the epoxy in sufficient quantity to render the adhesive 130 conductive.

It should be understood that while the adhesive 130 may be a conductive adhesive, example embodiments are not limited thereto and other mechanisms for electrically connecting the electronic package 120 with traces 110 may be used. By way of example, the adhesive 130 may be any suitable adhesive for physically bonding the electronic package 120 to traces 110 and/or the substrate 105, such as an epoxy or silicone adhesive. Contacts of the electronic package 120 may be electrically coupled to the conductive traces 110 by the adhesive 130 or by any any other suitable means, such as via wire bonding, die bonding, soldering, combinations thereof, and the like (all not shown). Regardless of its nature, the adhesive 130 may serve to bond the electronic package 120 within a mounting area of the substrate 105.

To reduce or prevent damage to the adhesive 130, stiffeners 140 may be placed proximate the mounting locations 115. In one embodiment, for example, the stiffeners may be coupled to a side of the substrate opposite from the side on which the electronic package 120 and the adhesive 130 are provided. The stiffeners 140 may be formed from a material and/or with a configuration that reduces or prevents flexing of the substrate in the mounting locations 115 compared to flexing of the substrate in the mounting locations 115 in the absence of the stiffeners 140. The stiffeners may be constructed from the same material as the substrate 105 or from a different material. For example, one or more of the stiffeners 140 may be constructed from fiberglass or a thermally conductive material. In an embodiment wherein the stiffeners 140 are a thermally conductive material, the stiffeners 140 may act as a heat sink to dissipate heat generated by the electronic packages 120.

The stiffeners 140 may be separately attached to a surface of the substrate 105 and/or may be included in the manufacture of the substrate 105, for example, by using several metal layers to increase the rigidity of the substrate 105 in the mounting locations 115. Also, the substrate 105 may have varying thicknesses and the stiffener 140 may be formed by the substrate 105 having a greater thickness in the mounting locations 115. Thus, the stiffeners 140 may include separate and distinct regions of stiffened material and/or multiple layers of stiffened material.

The stiffeners 140 reduce or prevent flexing of the substrate 105 in the area of the mounting locations 115 compared to flexing of said substrate 105 in the mounting locations 115 in the absence of the stiffener 115. The stiffeners 140 also allow one or more flexing zones 125 between mounting locations 115 to be formed on the substrate 105. For example, the flexing zones 125 may be established in locations surrounding or otherwise proximate to the edge of the stiffeners 140, but not within the interior of the stiffeners 140. By establishing the flexing zones 125 surrounding or otherwise proximate to the edge of the stiffeners 140, the stiffeners 140 may reduce or prevent the substrate 105 from bending or flexing within the mounting locations 115, while allowing greater flexing of the substrate 105 in the area of the flexing zones 125 between stiffeners 140 compared to flexing in the mounting areas 115. This allows the substrate 105 to bend to meet a desired shape while still protecting the damage to the adhesive connection in the mounting locations 115. In some embodiments, the light source 100 may be configured to bend to form an arc having a height greater than 25% of the length of the arc formed by bending substrate 105.

Advantageously, each stiffener 140 may reduce stresses in one or more mounting locations 115 imparted by movement or flexing of the substrate 105 that, in the absence of the stiffener 140, would cause the bond between the electronic package 120 and/or the substrate 105 and the adhesive 130 to crack and/or fail, potentially resulting in a loss of electrical connectivity between the electronic package 120 and conductive traces 110. Failure of the bond may be particularly problematic in instances where the substrate 105 is subject to bending forces that have a tendency to put significant stress on the bond between the electronic package 120 and the adhesive 130.

In the embodiment illustrated in FIG. 1, each of a plurality of stiffeners 140 are illustrated as horizontal strips spanning the width of the substrate 105 and extending across a plurality of the mounting locations 115. Embodiments consistent with the present disclosure are not limited to the stiffener configuration shown in FIG. 1 and the stiffeners 140 may have any geometry. For example, the stiffeners 140 may have a circular, elliptical or triangular shape. Potential benefits of a rectangular shape may be that the stiffeners 140 or easily manufactured or the flexing zones 125 may be controlled by the straight edge of the stiffener 140. Potential benefits of a circular shape may be that the stiffeners 140 have equal stiffness in all directions due to the properties of a circle. Potential benefits of a triangular shape may be that the stiffeners 140 have an increased rigidity due to properties of a triangle.

Also, while FIG. 1 illustrates the stiffeners 140 extending beyond the length and width of the electronic package 120 and the adhesive 130, example embodiments are not limited thereto and may vary. For example, the stiffeners 140 may extend beyond the length and/or width of the electronic package 120 and the adhesive 130, or the stiffeners may be shorter than the length and/or width of the electronic package 120 and the adhesive 130.

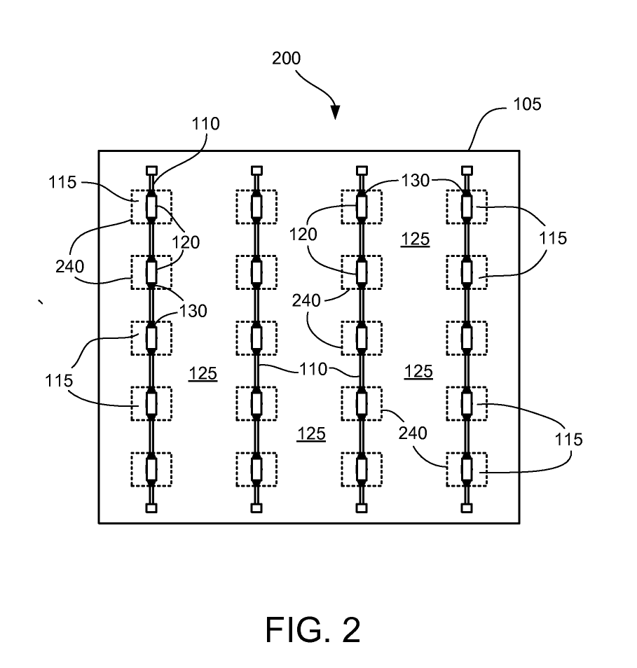

FIG. 2, for example, is a top view of another embodiment of a light source 200 including the substrate 105 having a plurality of electronic packages 120 consistent with the present disclosure. As shown, all of the elements of FIG. 2 are identical to those in FIG. 1, with the exception of the stiffeners 240. In the example embodiment of FIG. 2, each of the stiffeners 240 is a generally rectangular element, each of which is positioned proximate an associated one of the mounting locations 115, e.g. on a side of the substrate opposite from the electronic packages 120, and extends across a length and width an associated one of the electronic packages 120.

While FIG. 2 illustrates a width of the stiffener 240 being similar to a height of the stiffener 240, example embodiments are not limited thereto and may vary. For example, the width of the stiffener 240 may be greater than the height of the stiffener 240, or the width of the stiffener 240 may be less than the height of the stiffener 240. In addition, the shape of each stiffener 240 may vary, and a first stiffener 240 may be different than a second stiffener 240. While FIG. 2 illustrates the stiffener 240 having a rectangular shape, example embodiments are not limited thereto and the shape of the stiffener 240 may vary. For example, the stiffener 240 may have a circular, elliptical or triangular shape.

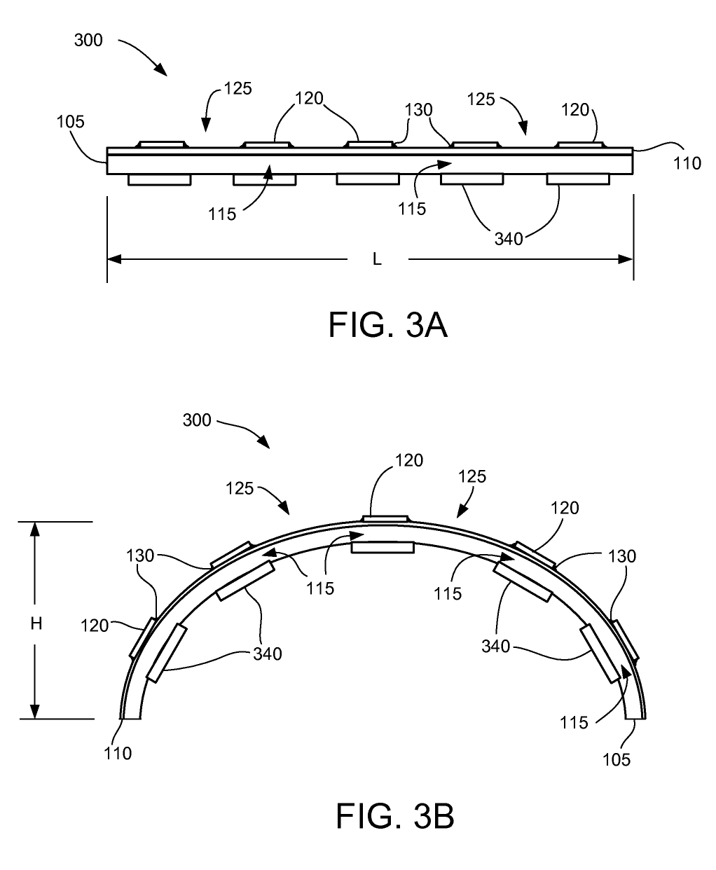

FIGS. 3A and 3B are a side view of a light source 300 consistent with the present disclosure in un-flexed and flexed states, respectively. The illustrated embodiment 300 includes the substrate 105 having a plurality of electronic packages 120. As shown in FIG. 3B, the substrate 105 may bend or flex, but each stiffener 340 may reduce the flexing (bending) of the substrate 105 in the mounting locations 115. Depending on the width of each stiffener 340, the substrate 105 when bent may have a general arc shape as shown in FIG. 3B. The bent shape may further include a series of localized flat surfaces associated with the mounting locations 115 where flexing of the substrate 105 is inhibited. Preferably, the arc shape formed by flexing the substrate 105 may have a height H which is at least 25% of the length of the arc, which in this case is the length L of the substrate 105.

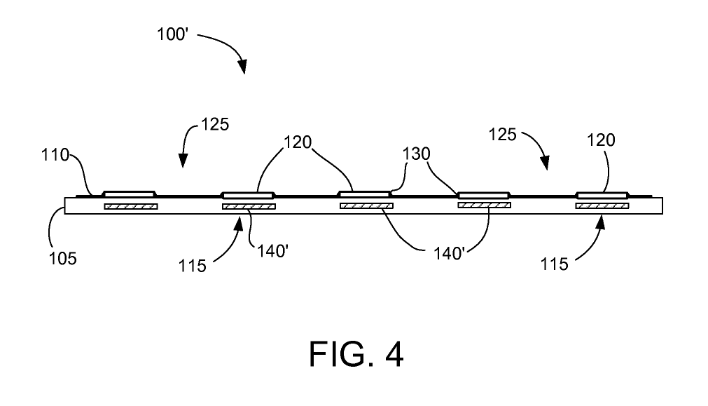

FIG. 4 is a cross sectional illustration of an embodiment similar to the embodiment shown in FIG. 1 in which the stiffeners 140′ of light source 100′ extend across a plurality of mounting locations 115. The cross section taken along a corresponding view A-A of FIG. 1 illustrates that the stiffeners 140′ are embedded (or laminated) within substrate 105 rather than attached to an underneath side as shown in FIG. 3A.

According to one aspect of the disclosure, there thus is provided a light source including a substrate; at least one electronic package coupled to the substrate by an adhesive at an associated mounting location; and a stiffener proximate to said mounting location for reducing flexing of the substrate in the mounting location compared to flexing of the substrate in the mounting location in the absence of the stiffener.

According to one aspect of the disclosure, there is provided a method of making a light source, including placing a stiffener proximate to a mounting location on a substrate of said light source, at least one electronic package coupled to said substrate by an adhesive at said mounting location, the stiffener configured to reduce flexing of said substrate in said mounting location compared to flexing of said substrate in said mounting location in the absence of said stiffener.

While the principles of the invention have been described herein, it is to be understood by those skilled in the art that this description is made only by way of example and not as a limitation as to the scope of the invention. Other example embodiments are contemplated within the scope of the present invention in addition to the example embodiments shown and described herein. Modifications and substitutions by one of ordinary skill in the art are considered to be within the scope of the present invention, which is not to be limited except by the following claims.

What is claimed is:

1. A light source, comprising:
a flexible substrate;
at least one electronic package coupled to said substrate by an adhesive at an associated mounting location; and
a stiffener proximate to said mounting location for reducing flexing of said substrate in said mounting location compared to flexing of said substrate in said mounting location in the absence of said stiffener.

2. The light source of claim 1, said light source comprising a plurality of electronic packages, each coupled to said substrate at an associated mounting location, and a plurality of said stiffeners, said light source comprising flexing zones between said associated mounting locations, said flexing zones having greater flexibility than a flexibility of said substrate in said associated mounting locations.

3. The light source of claim 1, said light source comprising a plurality of said electronic packages each coupled to said substrate at an associated mounting location, and wherein said stiffener extends across a plurality of mounting locations.

4. The light source of claim 1, said light source comprising a plurality of said electronic packages, each of said plurality of electronic packages being coupled to said substrate at an associated mounting location, wherein said light source comprises a plurality of said stiffeners, each of said plurality of stiffeners being positioned proximate an associated one of said mounting locations.

5. The light source of claim 1, wherein at least one of said stiffeners extends across a length and width of an associated one of said electronic packages.

6. The light source of claim 1, wherein said stiffener is coupled to a side of said substrate opposite from a side of said substrate on which said at least one electronic package is mounted.

7. The light source of claim 1, wherein at least one of said stiffeners is constructed from a different material from said substrate.

8. The light source of claim 1, wherein said light source is capable of bending to form an arc having a height greater than 25% of a length of the arc.

9. The light source of claim 1, wherein said at least one electronic package includes a light emitting diode.

10. The light source of claim 2, wherein said stiffeners are embedded within said substrate.

11. The light source of claim 2, wherein said stiffeners are laminated between layers of said substrate.

12. The light source of claim 2, wherein at least one of said stiffeners is constructed from a different material from said substrate.

13. A light source, comprising:
a flexible substrate;
at least one electronic package having a light emitting diode and being coupled to said substrate by an adhesive at an associated mounting location;
a stiffener proximate to said mounting location for reducing flexing of said substrate in said mounting location compared to flexing of said substrate in said mounting location in the absence of said stiffener; and
said light source being capable of bending to form an arc having a height greater than 25% of a length of the arc.

14. The light source of claim 13, said light source comprising a plurality of electronic packages, each coupled to said substrate at an associated mounting location, and a plurality of said stiffeners.

15. The light source of claim 13, wherein said stiffener is coupled to a side of said substrate opposite from a side of said substrate on which said at least electronic package is mounted.

16. The light source of claim 14, wherein said stiffeners are embedded within said substrate.

17. The light source of claim 14, wherein said stiffeners are laminated between layers of said substrate.
